(19) United States
(12) Patent Application Publication
(10) Pub. No.: US 2015/0373827 A1
(43) Pub. Date: Dec. 24, 2015

(54) Chip Heat Dissipation Structure and Terminal Device

(71) Applicant: Huawei Technologies Co., Ltd., Shenzhen (CN)

(72) Inventors: Junsheng Guo, Shenzhen (CN); Mingqiang Kuang, Shenzhen (CN); Lue Sun, Shenzhen (CN)

(21) Appl. No.: 14/815,160

(22) Filed: Jul. 31, 2015

Related U.S. Application Data
(63) Continuation of application No. PCT/CN2014/080532, filed on Jun. 23, 2014.

(51) Int. Cl. H05K 1/02; H01L 23/367; H05K 1/18

(52) U.S. Cl. CPC H05K 1/0203; H05K 1/18; H01L 23/3675

(57) ABSTRACT

A chip heat dissipation structure disposed on a printed circuit board (PCB), where the chip heat dissipation structure includes a chip card holder and at least one isolation groove; the chip card holder and the PCB are molded into one body; and the at least one isolation groove is disposed on the PCB and located around the chip card holder, and the at least one isolation groove is configured to isolate an area in which the chip card holder is located from another area on the PCB. The chip heat dissipation structure may be part of a terminal device.

### CROSS-REFERENCE

This application is a continuation of International Application PCT/CN2014/080532, filed on Jun. 23, 2014, which is hereby incorporated by reference in its entirety.

### TECHNICAL FIELD

The present disclosure relates to a chip heat dissipation structure and a terminal device that has the chip heat dissipation structure.

### BACKGROUND

With rapid development of communications technologies, the mobile Internet has been widely applied, for example, a wireless communications technology is applied to a vehicle-mounted positioning terminal system and a vehicle-mounted video to implement functions thereof, and a subscriber identification module (SIM) card needs to be carried so as to implement a function, such as signal transmission. A SIM card used in an existing vehicle-mounted terminal is fixed on a circuit board through a card holder. Because a high temperature is easily caused in a environment of vehicle-mounting and a central processing unit (CPU) and the like of a circuit board dissipate heat, the SIM card is easily distorted or damaged.

### SUMMARY

Embodiments of the present disclosure provide a chip heat dissipation structure, so as to reduce heat endured by a chip. The present disclosure further provides a terminal device that has the chip heat dissipation structure.

According to a first aspect, a chip heat dissipation structure is provided, where the chip heat dissipation structure is disposed on a printed circuit board (PCB), and the chip heat dissipation structure includes a chip card holder and at least one isolation groove, where the chip card holder and the PCB are molded into one body; and the at least one isolation groove is disposed on the PCB and located around the chip card holder, and the at least one isolation groove is configured to isolate an area in which the chip card holder is located from another area on the PCB.

In a first possible implementation manner of the first aspect, the area in which the chip card holder is located is connected to the another area on the PCB through a connecting area.

With reference to the first possible implementation manner of the first aspect, in a second possible implementation manner, the at least one isolation groove is a bar structure, and the isolation groove is disposed from one side of the connecting area and along an edge of the chip card holder.

With reference to the first possible implementation manner of the first aspect, in a third possible implementation manner, the isolation groove is separated into at least two through grooves, where the at least two through grooves are disposed around the chip card holder.

According to a second aspect, a terminal device is provided, where the terminal device includes the chip heat dissipation structure according to any one of the first to the third possible implementation manners.

In conclusion, a chip card holder of a chip heat dissipation structure in the present disclosure is isolated from another part on a circuit board through at least one isolation groove, which reduces heat, which is transferred to the chip card holder through the circuit board, at another position on the circuit board, thereby reducing heat of the chip card holder and preventing a chip in the chip card holder from being distorted or damaged.

### BRIEF DESCRIPTION OF DRAWINGS

To describe the technical solutions in the embodiments of the present disclosure more clearly, the following briefly introduces the accompanying drawings required for describing the embodiments. The accompanying drawings in the following description show merely some embodiments of the present disclosure, and a person of ordinary skill in the art may still derive other drawings from these accompanying drawings without creative efforts.

FIG. 1 is a schematic plan diagram of a chip heat dissipation structure according to an embodiment of the present disclosure;

FIG. 2 is a schematic plan diagram of a chip heat dissipation structure according to another embodiment of the present disclosure;

FIG. 3 is a structural block diagram of a terminal device according to an embodiment of the present disclosure; and

FIG. 4 is a structural block diagram of a terminal device according to another embodiment of the present disclosure.

### DESCRIPTION OF EMBODIMENTS

The present disclosure provides a chip heat dissipation structure, which can reduce heat that is endured by a chip in an external environment, thereby preventing the chip from being distorted due to an overhigh temperature.

To make a person skilled in the art understand the technical solutions in the present disclosure better, the following clearly describes the technical solutions in the embodiments of the present disclosure with reference to the accompanying drawings in the embodiments of the present disclosure. The described embodiments are merely a part rather than all of the embodiments of the present disclosure. All other embodiments obtained by a person of ordinary skill in the art based on the embodiments of the present disclosure without creative efforts shall fall within the protection scope of the present disclosure.

FIG. 1 is a schematic plan diagram of a chip heat dissipation structure according to an embodiment of the present disclosure. As shown in FIG. 1, the chip heat dissipation structure provided in this embodiment of the present disclosure is disposed on a PCB 10 (of a terminal device. The chip heat dissipation structure includes a chip card holder 20 and at least one isolation groove 30, and the chip card holder 20 and the PCB 10 are molded into one body. The at least one isolation groove 30 is disposed on the PCB 10 and located around the chip card holder 20, and so that an area in which the chip card holder 20 is located is isolated from another area of the PCB 10, thereby implementing isolation of heat dissipation of a chip inside the chip card holder 20.

In this embodiment, the chip heat dissipation structure may be applied to a mobile terminal, such as a vehicle-mounted terminal, a mobile phone, or a tablet computer. The chip may be a SIM card or may be a storage card. The chip card holder 20 is configured to carry the chip, and an electrical connection terminal that connects to the chip inside the chip card holder 20 is directly disposed on the printed circuit board 10. For the SIM card, when the SIM card is disposed in a terminal device such as a vehicle-mounted device, because a high temperature is easily caused in an internal environment of the terminal and a CPU and the like of the circuit board dissipate heat, the SIM card is easily distorted or damaged; therefore, at least one isolation groove 30 is disposed around the chip card holder 20 so as to isolate the chip card holder 20 from another part of the PCB 10, which avoids that heat that is generated by a component such as the CPU on the circuit board is transferred to the chip card holder 20 through the circuit board, and reduces heat of the chip card holder 20, thereby preventing the chip inside the chip card holder 20 from being distorted or damaged.

Further, a connecting area 15 is disposed between an area in which the PCB 10 carries the chip card holder 20 and another area of the PCB 10, and is configured to arrange wiring of the chip card holder 20 and wring of the PCB 10. The area in which the chip card holder 20 is carried is a carrying area 16. The another area of the PCB 10 is a mainboard area 17. The connecting area 15 connects the carrying area 16 and the mainboard area 17, so that the connecting area 15 connects the chip card holder 20 and a layout of a signal line of the PCB 10.

Further, the isolation groove 30 is a bar structure. The isolation groove 30 separates the carrying area 16 and the mainboard area 17, so as to reduce heat that is generated by a component on the printed circuit board 10 and transferred to the carrying area 16.

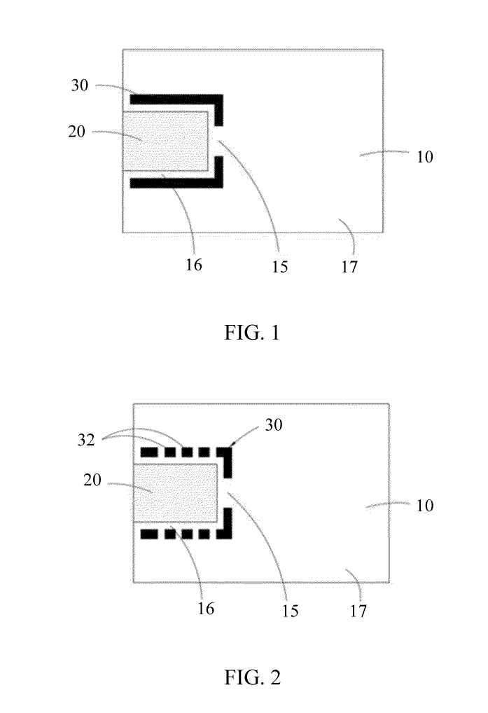

Referring to FIG. 2, in another embodiment of the present disclosure, the isolation groove 30 is separated into at least two through grooves 32, where the at least two through grooves 32 are disposed around the chip card holder 20, and the at least two through grooves 32 penetrate the PCB 10. In this embodiment, there are multiple through grooves 32 and the through grooves 32 are disposed at an interval. The multiple through grooves 32 are arranged from one side of the connecting area to form a breakpoint strip around the chip card holder 20, and the number of the through grooves 32 is set according to a design requirement of the chip card holder 20. The breakpoint strip formed by the multiple through grooves 32 disposed at an interval isolates the chip card holder 20, which meets a connecting requirement of a medium layer of the circuit board. The signal line on the PCB 10 may pass through a part between every two through grooves 32, which can ensure signal quality and can further ensure a requirement for anti-vibration and deformation of the circuit board.

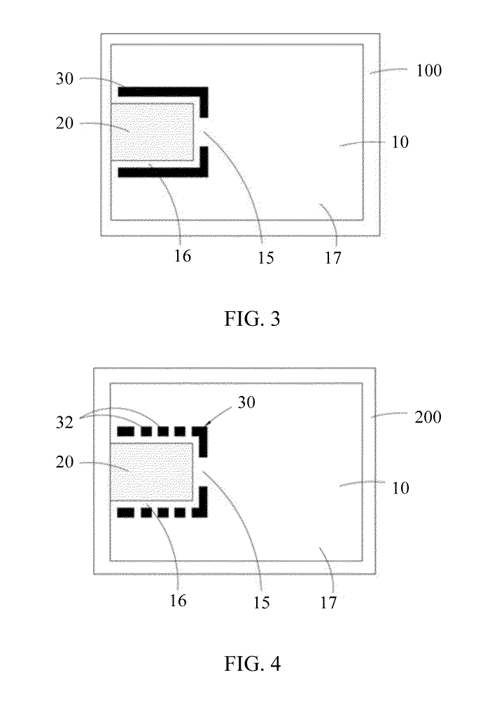

Referring to FIG. 3, the present disclosure further provides a terminal device 100, where the terminal device 100 includes the PCB 10 and the chip heat dissipation structure provided in the embodiment of the present disclosure and shown in FIG. 1. The chip heat dissipation structure is configured to carry a chip and perform heat dissipation for the chip, the chip card holder 20 is connected to the PCB 10 electrically by means of wiring, and the wiring is arranged in the connecting area 15.

In another embodiment of the present disclosure, other electronic components, such as a central processing unit (not shown in the figure) and a power processor (not shown in the figure) are further disposed on the PCB 10. The power processor implements an electrical connection between the chip inside the chip card holder 20 and the central processing unit, and the central processing unit implements running of the terminal device 100. Because an isolation groove is disposed on an edge of the chip card holder 20, heat generated by an electronic component on the PCB 10, such as the central processing unit, is isolated by the isolation groove, which reduces heat, which is transferred to the chip card holder 20 through the circuit board, of a component, such as the CPU, on the circuit board, and reduces a probability of damage to the chip inside the chip card holder 20 and damage to an electrical connection terminal that connects to the chip, thereby improving stability of the terminal device 100. Referring to FIG. 4, the present disclosure further provides a terminal device 200, where the terminal device 200 includes the PCB 10 and the chip heat dissipation structure provided in the another embodiment of the present disclosure and shown in FIG. 2. The chip heat dissipation structure is configured to carry a chip and perform heat dissipation for the chip, the chip card holder 20 is connected to the PCB 10 electrically by means of wiring, and the wiring is arranged in the connecting area 15. The breakpoint strip, which is formed by the multiple through grooves 32 disposed at an interval, of the chip heat dissipation structure isolates the chip card holder 20, which meets a connecting requirement of a medium layer of the circuit board. The signal line on the PCB 10 may pass through a part between every two through grooves 32, which can ensure signal quality and can further ensure stability of the terminal device 200.

The foregoing descriptions are exemplary implementation manners of the present disclosure. It should be noted that a person of ordinary skill in the art may make several improvements and polishing without departing from the principle of the present disclosure and the improvements and polishing shall fall within the protection scope of the present disclosure.

What is claimed is:

1. A chip heat dissipation structure comprising:
a chip card holder; and
at least one isolation groove,
wherein the chip heat dissipation structure is disposed on a printed circuit board (PCB), wherein the chip card holder and the PCB are molded into one body, wherein the at least one isolation groove is disposed on the PCB and located around the chip card holder, and wherein the at least one isolation groove is configured to isolate an area in which the chip card holder is located from another area on the PCB.

2. The structure according to claim 1, wherein the area in which the chip card holder is located is connected to the another area on the PCB through a connecting area.

3. The structure according to claim 2, wherein the at least one isolation groove is a bar structure, and wherein the isolation groove is disposed from one side of the connecting area and along an edge of the chip card holder.

4. The structure according to claim 2, wherein the isolation groove is separated into at least two through grooves, and wherein the at least two through grooves are disposed around the chip card holder.

5. The structure according to claim 1, wherein the chip dissipation structure is part of a terminal device.

6. The structure according to claim 5, wherein the chip heat dissipation structure is configured to carry a chip and perform heat dissipation for the chip, wherein the chip card holder is electrically connected to the PCB by means of wiring, and wherein the wiring is arranged in a connecting area.

7. A terminal device comprising:
a chip heat dissipation structure comprising:
a chip card holder; and
at least one isolation groove,
wherein the chip heat dissipation structure is disposed on a printed circuit board (PCB), wherein the chip card holder and the PCB are molded into one body, wherein the at least one isolation groove is disposed on the PCB and located around the chip card holder, and wherein the at least one isolation groove is configured to isolate an area in which the chip card holder is located from another area on the PCB.

8. The terminal device according to claim 7, wherein the chip heat dissipation structure is configured to carry a chip and perform heat dissipation for the chip, wherein the chip card holder is electrically connected to the PCB by means of wiring, and wherein the wiring is arranged in a connecting area.
